(19) United States
(12) Patent Application Publication
(10) Pub. No.: US 2024/0363720 A1
(43) Pub. Date: Oct. 31, 2024

(54) SEMICONDUCTOR DEVICE WITH LOW CONCENTRATION OPPOSITE TYPE DOPING DRAIN END GATE ELECTRODE

(71) Applicant: Texas Instruments Incorporated, Dallas, TX (US)

(72) Inventor: Henry Litzmann Edwards, Garland, TX (US)

(21) Appl. No.: 18/459,065

(22) Filed: Aug. 31, 2023

Related U.S. Application Data
(60) Provisional application No. 63/462,710, filed on Apr. 28, 2023.

(51) Int. Cl. H01L 29/49; H01L 21/3215; H01L 29/06; H01L 29/40; H01L 29/66; H01L 29/78

(52) U.S. Cl. CPC H01L 29/4983; H01L 21/32155; H01L 29/0653; H01L 29/401; H01L 29/402; H01L 29/66681; H01L 29/7816

(57) ABSTRACT

Disclosed examples include microelectronic devices, e.g. integrated circuits, that include a source region and a drain region extending into a semiconductor substrate, the semiconductor substrate having a second conductivity type, the source region and drain region having an opposite first conductivity type. A channel region having the second conductivity type extends between the source region and the drain region. A gate electrode over the channel region has a first portion and a second portion. The first portion has the second conductivity type and a first dopant concentration. The second portion extends from the first portion toward the source region and has the second conductivity type and a second higher dopant concentration.

### TECHNICAL FIELD

This disclosure relates to the field of microelectronic devices. More particularly, but not exclusively, this disclosure relates to gated devices such as MOS transistors.

### BACKGROUND

Semiconductor components are being continually improved to reliably operate with smaller feature sizes. Fabricating semiconductor devices that have increasingly higher performance while meeting reliability specifications is challenging.

### SUMMARY

This summary is provided to introduce a brief selection of disclosed concepts in a simplified form that are further described below in the detailed description including the drawings provided. This summary is not intended to limit the claimed subject matter's scope.

Disclosed examples include microelectronic devices, e.g. integrated circuits. One such example includes a source region and drain region extending into a semiconductor substrate, the semiconductor substrate having a second conductivity type, and the source region and the drain region having an opposite first conductivity type. A channel region having the second conductivity type extends between the source region and the drain region. A gate electrode over the channel region has a first portion and a second portion. The first portion has the second conductivity type and a first dopant concentration. The second portion extends from the first portion toward the source region and has the second conductivity type and a second higher dopant concentration.

Disclosed examples further include methods of forming an integrated circuit. In one example a method includes forming source and drain regions having a first conductivity type extending into a semiconductor substrate having an opposite second conductivity type. A gate electrode is formed over the semiconductor substrate between the source region and the drain region, the gate electrode having first and second portions having the second conductivity type. The first portion is between the second portion and the drain region and has a first dopant concentration, and the second portion has a second higher dopant concentration.

### BRIEF DESCRIPTION OF THE VIEWS OF THE DRAWINGS

FIG. 1A through FIG. 1F are cross sections of an example microelectronic device including a transistor with a depletable resurf gate electrode in various stages of formation.

FIG. 2 is a graph showing the gate electrode doping profile for an example microelectronic device with a depletable resurf gate electrode from FIG. 1A through FIG. 1F.

FIG. 3A through FIG. 3F are cross sections of an LDMOS transistor with a depletable resurf gate electrode in various stages of formation.

FIG. 4 is a graph showing the gate electrode doping profile for the LDMOS transistor with a depletable resurf gate electrode from FIG. 3A through FIG. 3F.

FIG. 5 is a top-down view of an LDMOS transistor with a depletable resurf gate electrode in a racetrack configuration

FIG. 6 is a cross section of a DENMOS transistor with a depletable resurf gate electrode.

FIG. 7 is a graph comparing the electric field in the channel under the gate electrode between the source region and the drain region for a reference transistor and a transistor with a depletable resurf gate electrode.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, the term “approximately,” as used herein, may refer to ±5% to ±10% variations of the recited values in some cases. In other cases, the term “approximately” may refer to ±10% to ±20% variations of the recited values.

Microelectronic devices are being continually improved to reliably operate with higher performance and smaller feature sizes. Fabricating such microelectronic devices satisfying area scaling and reliability requirements is challenging. Certain gate-controlled devices such as metal-oxide-semiconductor (MOS) transistors include features for supporting high voltage operations, e.g. with a voltage applied to their drain (or drain structure) of about 20 V, 30 V, 40 V, or even greater. Such MOS transistors may include drain diffusion profiles (or drain junction profiles) devised to support the high voltages applied to the drain, e.g having an extended portion to distribute the voltage drop across greater distances. Accordingly, such MOS transistors may be referred to as drain-extended MOS transistors, for example drain-extended n-channel MOS (DENMOS) transistors, drain-extended p-channel MOS (DEPMOS) transistors, laterally-diffused MOS (LDMOS) transistors, as well as groups of DENMOS and DEPMOS transistors (which may be referred to as complimentary drain-extended MOS or DECMOS transistors). Other gate controlled microelectronic devices may include a gated bipolar semiconductor device, a gated unipolar semiconductor device, an insulated gate bipolar transistor (IGBT), a metal oxide semiconductor (MOS)-triggered SCR, a MOS-controlled thyristor, and a gated diode.

Conventional field-effect transistors typically have a gate electrode over a channel region, wherein the gate electrode is doped a same conductivity type as the channel region, the channel region in turn being between a source region and a drain region having an opposite conductivity type. Thus, when the transistor is in an off state, the gate electrode has an opposite majority carrier type than the majority carrier type of the channel region. For example, a conventional n-type transistor, e.g. an n-channel MOSFET, has a p-type body region before channel inversion, and the gate electrode is typically heavily doped for high conductivity. In the case of extended-drain (ED) transistors, the operating voltage may be limited by avalanche breakdown at the drain-to-body junction, the breakdown often occurring at the silicon surface. In contrast, examples of the present disclosure include the innovative recognition that by doping the drain end of the gate electrode with a light doping of the opposite doping type of the majority charge carrier of the channel under inversion (e.g. electrons for an n-channel device), the gate electrode can be depleted by the electric field produced by the drain at high drain voltages. In this manner, the gate electrode may act as a semiconductor “resurf” element, resurf referring to REduced SURface Field. The gate electrode of the example devices may be referred to as a “depletable resurf gate electrode”, as the carriers in the gate electrode are depleting at the same time as the carriers in the drain drift region of the ED device example. The electrons and holes mutually deplete each other due to the electric field from the junction reverse bias. This results in a reduction of the electric field in the gate oxide at the drain end of the gate electrode which reduces aging in the microelectronic device by reducing failure mechanisms such as channel hot carrier (CHC) and gate oxide rupture. In this manner device reliability may be improved and/or device size may be reduced.

By way of further background, the gate electrode of an operating ED transistor performs the important function of controlling the silicon surface potential in the channel region. The bottom of the portion of the gate electrode overlying the channel must enforce a metallic boundary condition during gate switching in order to control the surface potential of the underlying channel silicon, forcing the silicon surface carrier profile into accumulation (transistor gate off-state), through depletion (sub-threshold), and eventually to strong inversion (on-state), as the gate electrode is changed from 0 V to a positive on-state voltage (NMOS transistor) or a negative on-state voltage (PMOS transistor).

In order to achieve this channel surface potential control, the portion of a semiconducting gate electrode whose lower surface lies over the channel must have a high dopant concentration, since maintaining a metallic boundary condition requires that the vertical electric field in the gate dielectric be screened by free carriers to result in a zero electric field within the conductive interior of this portion of the gate electrode. Obtaining a sufficiently high concentration of free carriers requires a high concentration of majority carrier doping in the portion of the gate electrode that lies over the channel. In some examples it is desirable that the dopant concentration in the channel be at least high enough that the carrier profile is degenerate, or at least 1×10¹⁹ cm⁻³.

At the drain end of the gate electrode, the doping profile of the drain region underlaps the gate electrode. In the transistor gate off-state, and particularly when the drain region is held at a high reverse bias (commonly referred to as the blocking state), the majority carriers in this drain underlap portion of the gate electrode will deplete, exposing ionized majority carrier dopants. If the doping type of the gate electrode overlying the drain region is the same as that of the drain, then majority carriers will be attracted to the bottom of the gate electrode near and including its drain end and will form an accumulation layer that provides a metallic boundary condition. This causes a high local high electric field in the gate dielectric near the drain end and, at the bottom drain-facing corner of the gate electrode, the electric field may be intensified by the curvature of the gate electrode corner. This localized peak in electric field may be high enough to cause transistor degradation mechanisms such as channel hot carrier (CHC) injection or dielectric failure in the gate dielectric, which can pose severe restrictions on transistor usage at elevated drain blocking voltages.

Examples consistent with the disclosure provide doping in the drain end of the gate that has a conductivity type, e.g. p-type, opposite the conductivity type of the doping of the drain, e.g. n-type. In this configuration the majority carriers in the drain end of the gate electrode may deplete under the action the electric field caused by drain in a reverse bias state. Furthermore, in various examples the majority carrier concentration in the drain end of the gate electrode may be low enough to deplete without undergoing breakdown, as is ensured by the resurf condition of having a dopant dose below 1×10¹³ cm⁻². A significant portion of the gate (for example even wider than the gate electrode thickness) can be depleted during drain reverse bias, turning this portion of the gate electrode into a charged dielectric region that counter-balances the exposed charges in the underlying silicon due to the opposite doping sign. This charge balance alleviates the high surface electric fields over the entire overlap region between the drain doping profile and the gate electrode, enabling drain extended transistor operation at high blocking drain voltages without incurring the degradation effects of high local electric fields, especially when operating in pulsed mode. This mutual-depletion effect between the drain carrier profile and the carrier profile in the drain-facing end of the gate electrode is similar to the mutual depletion of an n-layer and a p-layer in a resurf drift region, so we refer to a drain extended transistor employing this gate electrode doping profile as a depletable resurf gate electrode drain extended transistor.

The extent of the depletion of the drain-facing end of the gate electrode should be limited so that it does not extend to source-end features such as a silicide on the top surface of the gate electrode, to avoid breakdown effects such as avalanching. To suppress such an effect, in some examples the doping concentration of the gate electrode increases as it approaches any surface silicide or other feature that could cause breakdown.

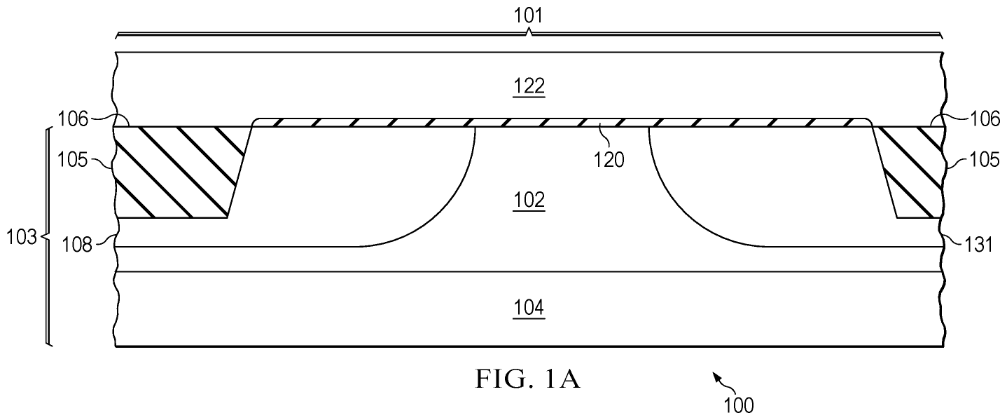

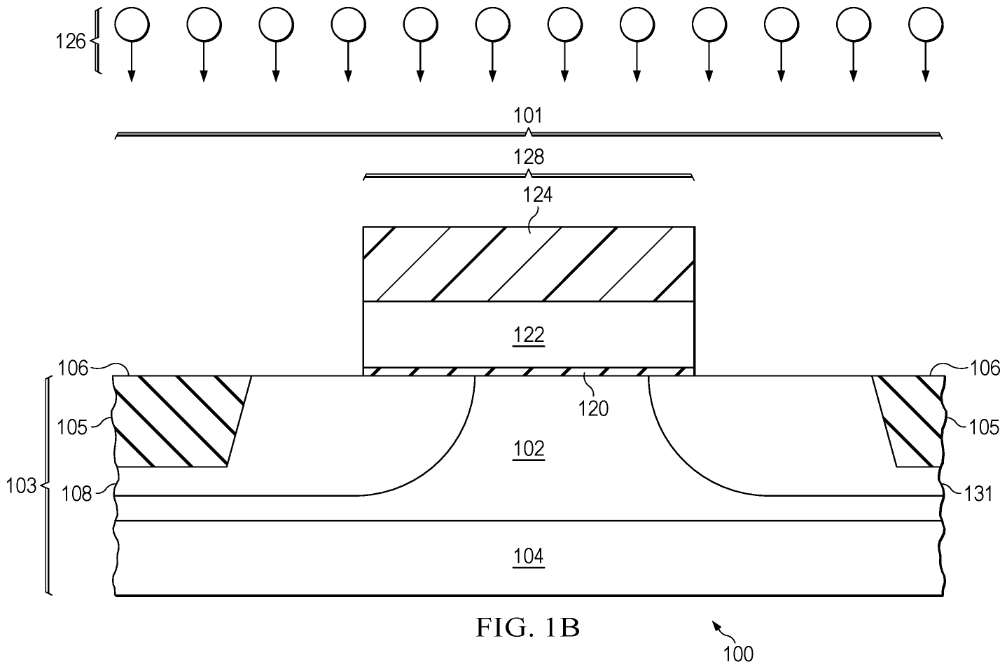

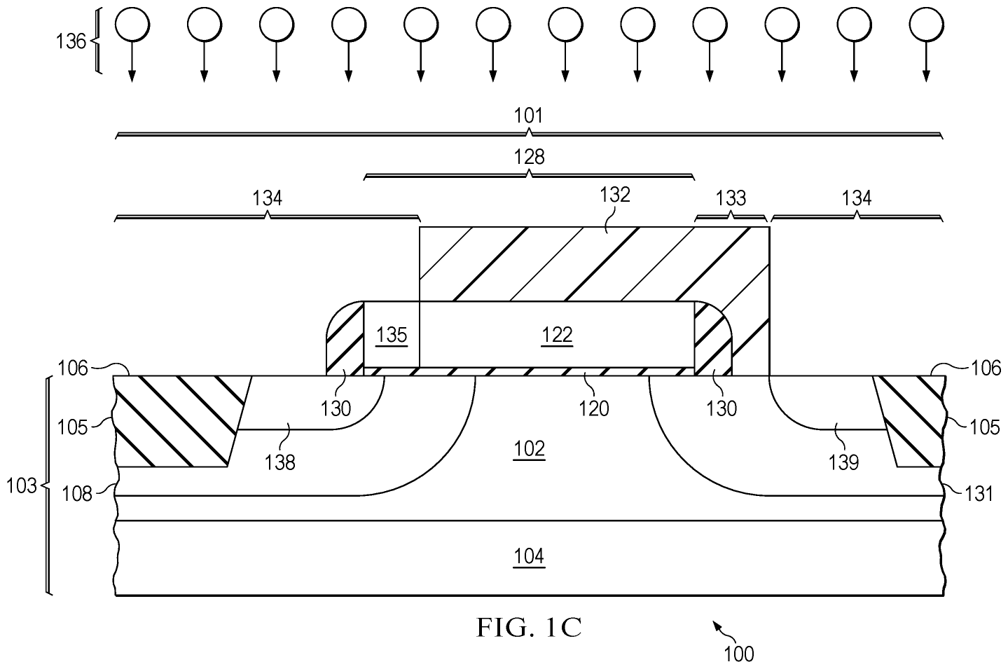

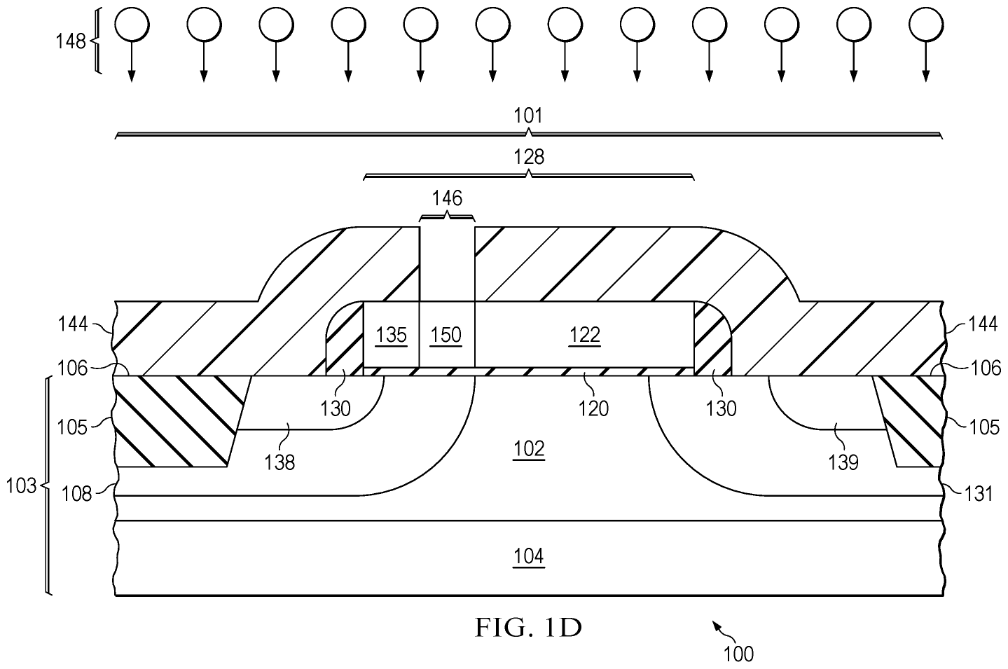

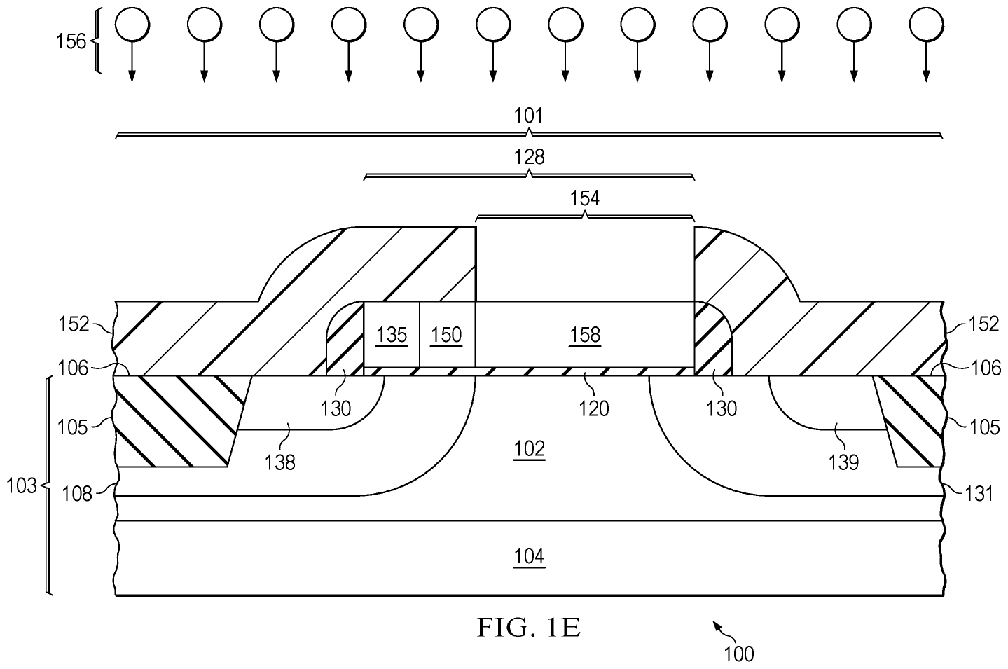

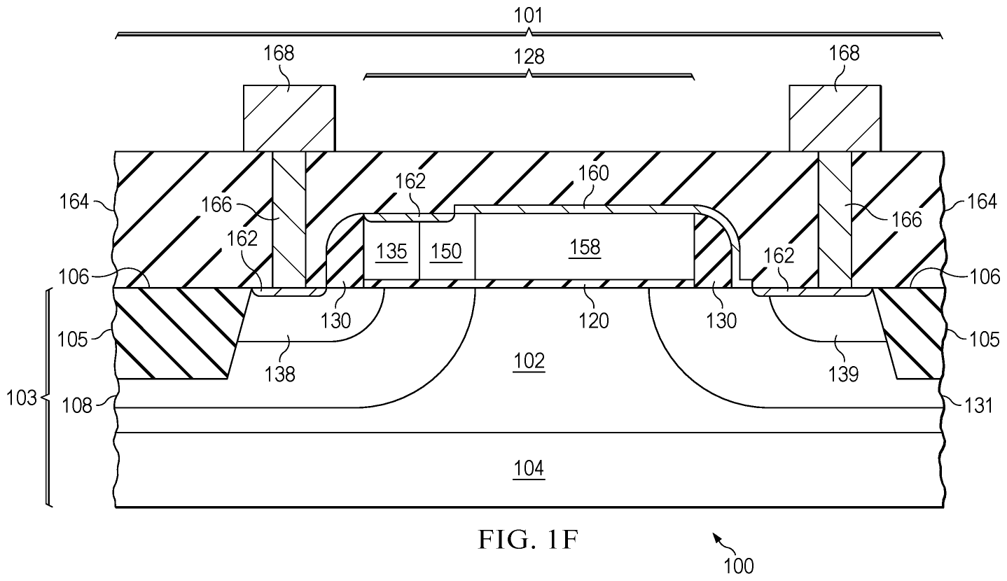

FIG. 1A through FIG. 1F are representative of a first type of electronic device to which the principles of the disclosure may be beneficially applied. These figures show cross sections of an example microelectronic device 100, e.g. a MOS transistor, including a depletable resurf gate electrode 128 (FIG. 1B, et seq.) herein referred to as the gate electrode 128. Without implied limitation, the gate electrode 128 in this example is implemented in an n-type metal oxide semiconductor (NMOS) transistor 101 which is shown in successive stages of an example method of formation. Other implementations for the gate electrode 128 in a PMOS transistor are within the scope of this example. In the example NMOS transistor 101, dopants of a first conductivity type are n-type dopants and dopants of a second conductivity type are p-type dopants.

FIG. 1A shows the microelectronic device 100 including the NMOS transistor 101 after the formation of a gate dielectric layer 120 and a gate polysilicon layer 122. The structures and method within the microelectronic device 100 formed before the gate dielectric layer 120 formation may include an epitaxial layer 102 over a base wafer 104, together referred to as a substrate 103 with a top surface 106. The base wafer 104 may be p-type silicon with a dopant concentration of 1×10¹⁷ cm⁻³ to 1×10¹⁹ cm⁻³, for example. Alternatively, the base wafer 104 may be lightly doped, with an average dopant concentration below 1×10¹⁶ cm⁻³. The epitaxial layer 102 may be p-type silicon with a dopant concentration of 1×10¹⁵ cm⁻³ to 1×10¹⁶ cm⁻³, by way of example. The epitaxial layer 102 is optional in that the NMOS transistor 101 may be formed directly in the base wafer 104 in some examples.

An isolation layer for the NMOS transistor may be formed by either by shallow trench isolation (STI) or local oxidation of silicon (LOCOS), either of which may be conventional or by any future-discovered method. The illustrated example includes STI structures 105.

In the substrate 103, a p-type well region 108 (DWELL) is also formed. The p-type well region 108 is implanted with p-type dopants which may include boron and/or indium. The p-type well region 108 may have a peak dopant density between 3×10¹⁶ cm⁻³ and 1×10¹⁹ cm⁻³ at a depth between 0.5 μm and 1.5 μm below the top surface 106. The p-type well region 108 (in conjunction with the epitaxial layer 102 in some examples) may be referred to a body region (e.g., p-type body region) of the NMOS transistor 101. Additionally, in the substrate 103, a n-type well region 131 is also formed. The n-type well region 131 is doped with n-type dopants which may include phosphorus or arsenic by way of example. The n-type well region 131 may have a peak dopant density between 3×10¹⁶ cm⁻³ and 1×10¹⁹ cm⁻³ at a depth between 0.5 μm and 1.5 μm below the top surface 106.

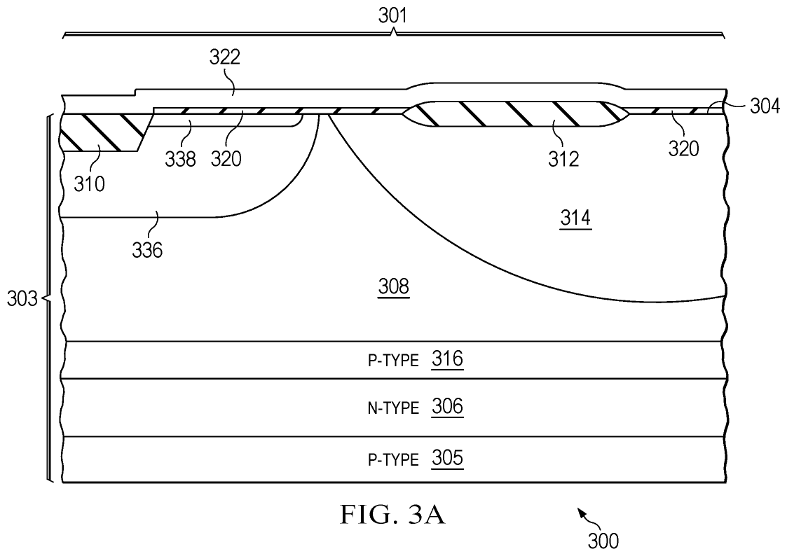

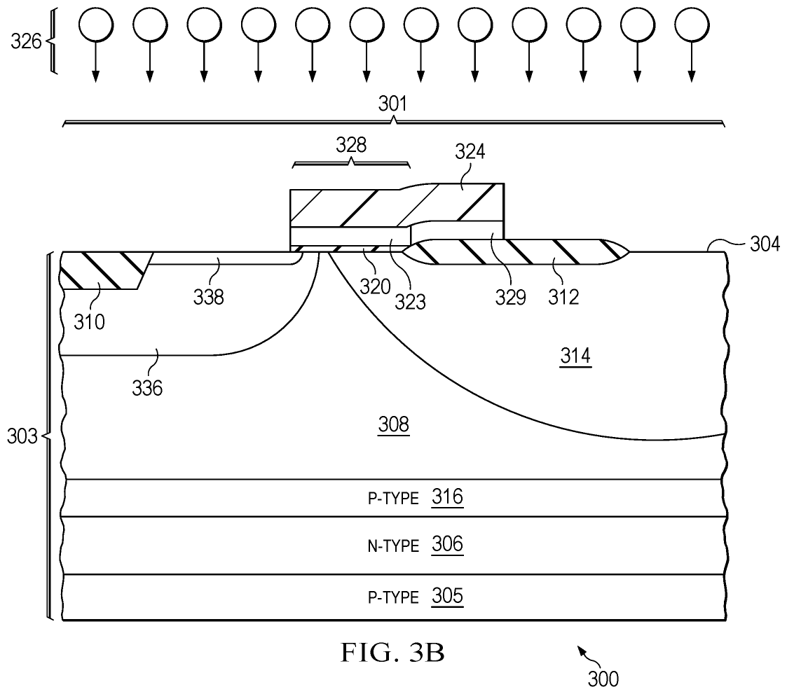

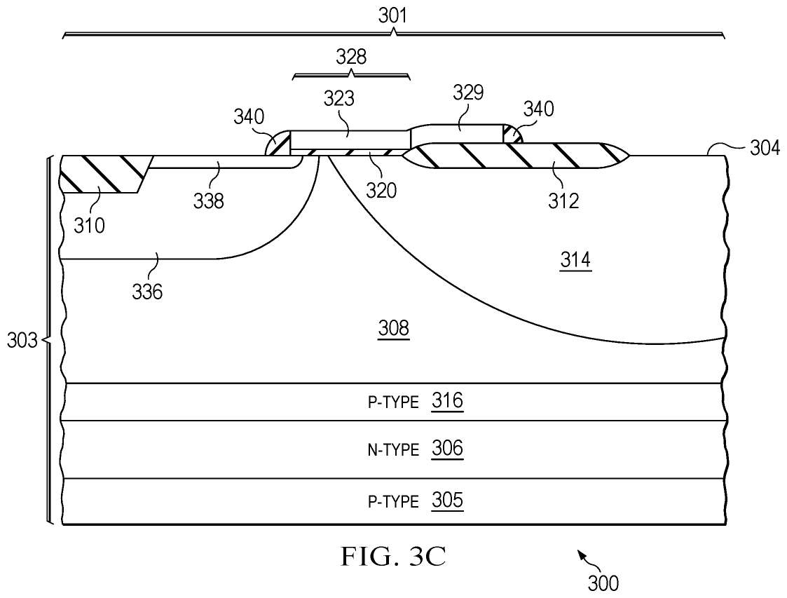

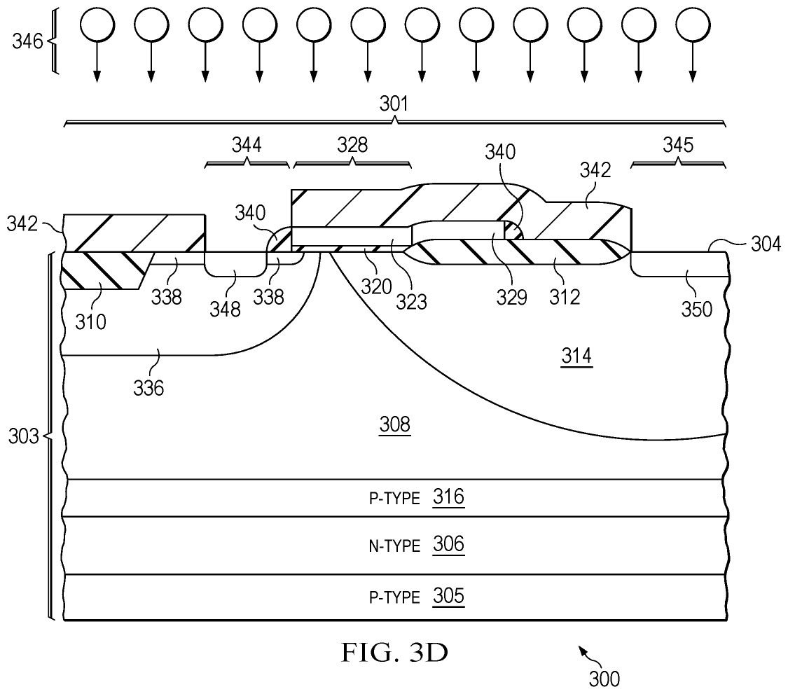

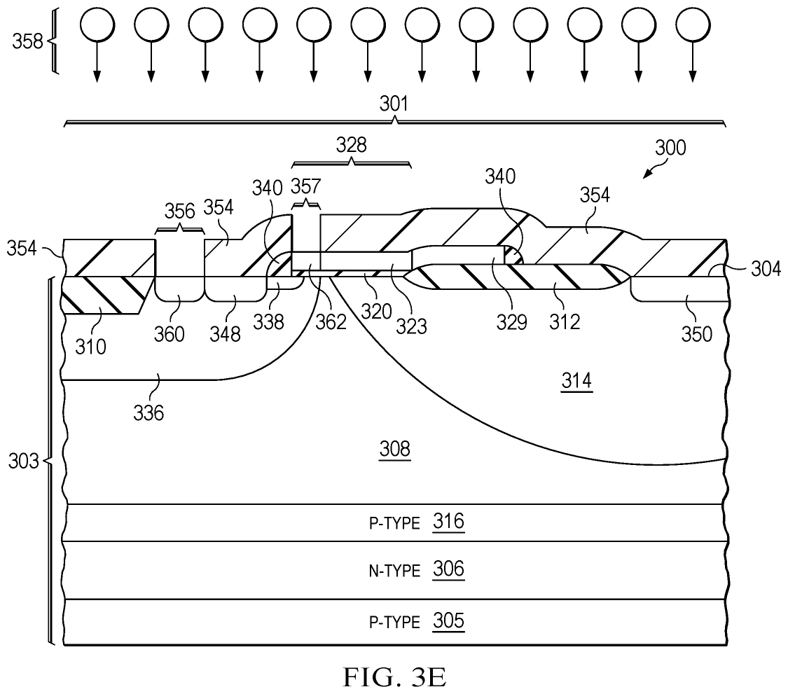

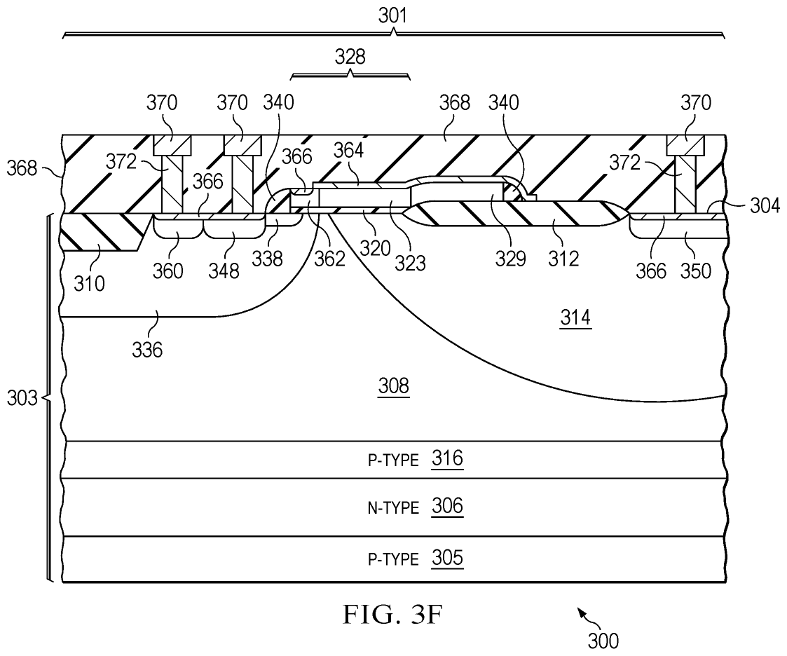

While not limited to the features discussed above in FIG. 1A which are formed in the substrate 103 of the NMOS transistor 101, the gate dielectric layer 120 and gate polysilicon layer 122 are formed over the top surface 106. The gate dielectric layer 120 may be formed in a high temperature furnace operation or a rapid thermal process. Other methods of forming the gate dielectric layer 120 are within the scope of this disclosure. The gate dielectric layer 120 may be any material and have any thickness appropriate to the technical application. The gate polysilicon layer 122 is formed on the gate dielectric layer 120 by a conventional of future-discovered method. In the illustrated example, the gate polysilicon layer 122 is formed by a deposition process using one or more silane-based precursors to deposit polycrystalline silicon (which may be referred to as polysilicon). In other examples, a replacement gate process may be used to form the gate polysilicon layer 122. The gate polysilicon layer 122 has a thickness that may range from approximately 50 nm to 300 nm. The gate polysilicon layer 122 is a semiconductor layer and may be undoped or doped as-deposited. The gate polysilicon layer 122 may also be a poly-SiGe layer, a poly-Ge layer, a poly-SiC layer, or another semiconductor that can be grown or deposited on a gate dielectric. In the example shown in FIG. 1A, the gate polysilicon layer 122 is undoped. (FIG. 3A refers to an example in which the polysilicon is doped as deposited).

FIG. 1B shows a cross section of the NMOS transistor 101 after a gate resist 124 has been formed and after a gate plasma etch 126. The gate plasma etch 126 removes previously formed gate dielectric layer 120 and the gate polysilicon layer 122 in areas not covered by the gate resist 124. The area under the gate resist 124 defines a gate electrode 128, the gate electrode 128 being the gate polysilicon layer 122 and gate dielectric layer 120 remaining after the gate plasma etch 126. After the gate plasma etch 126 is complete, the gate resist 124 is removed and a wet or dry process may be used to clean the wafer surface.

Referring to FIG. 1C, sidewall spacers 130 may be formed on the vertical surfaces of the gate electrode 128, and may extend 50 nm to 200 nm from the lateral edge of the gate electrode 128. After the formation of the sidewall spacers 130, a first source and drain resist 132 is deposited and patterned. A first source/drain implant 136 implants n-type dopants through a source/drain opening 134 into the substrate 103 to implant the source region 138, the drain region 139, and a portion 135 of the gate electrode. The first source/drain implant 136 may include one or more implant steps, with conditions such that resulting the source region 138, drain region 139, and portion 135 of the gate electrode 128 have a dopant concentration peaking between 1×10¹⁹ cm⁻³ and 1×10²¹ cm⁻³. The doping level implanted in the portion 135 of the gate electrode is such that it does not deplete during the operation of the NMOS transistor 101. The source region 138 and drain region 139 contain an average dopant density at least twice that of the epitaxial layer 102 with the peak doping density between 0.5 μm and 1.5 μm from the top surface 106. A source/drain resist extension 133 extends the resist past the end of the gate electrode 128 towards the drain region 139. The source/drain resist extension 133 prevents n-type dopants from the first source/drain implant 136 from extending under the gate electrode 128 after subsequent thermal annealing processes. After the formation of the source region 138 and the drain region 139, the source and drain resist 132 is removed.

FIG. 1D refers to a cross section of the NMOS transistor 101 after a second source/drain implant resist 144 is deposited and patterned to a form an opening 146 for a second source/drain implant 148. The second source/drain implant 148 may implant dopants for a second source/drain region for p-channel devices (not specifically shown) of the microelectronic device 100. Additionally, the second source/drain implant 148 implants p-type dopants through the opening 146 to form a portion 150 of the gate electrode 128 which is heavily p-type doped.

As with the first source/drain implant 136, the second source/drain implant 148 may occur in one or more steps. The second source/drain implant 148 may implant species including boron (or indium) with an overall dose and energy such that they provide degenerate doping of the portion 150 of the gate electrode 128, e.g., having an active average dopant density greater than 1×10¹⁹ cm⁻³ near the solubility limit of the dopant atoms in the gate electrode 128. After the second source/drain implant 148, the second source/drain implant resist 144 is removed.

FIG. 1E shows a cross section after a resurf resist 152 is deposited and patterned with an opening 154. A resurf implant 156 uses ion-implantation to implant p-type dopants to form a first portion 158 of the gate electrode 128. In the remaining discussion the gate electrode portions 158, 150 and 135 may respectively be referred to as first portion 158, second portion 150 and third portion 135. In the first portion 158 of the gate electrode 128, the resurf region, the p-type doping density is low enough to allow depletion during operation of the NMOS transistor 101 and allow it to function as a resurf region. The resurf implant 156 may occur in one or more steps with implant species including one or more of boron or indium with an overall dose of between 1×10¹² cm⁻² and 1×10¹³ cm⁻². The second portion 150 of the gate electrode 128 provides a heavily doped p-type region (greater than 1×10¹⁸ cm⁻³) between the third portion 135 which is heavily n-type doped (greater than 1×10¹⁸ cm⁻³) and the first portion 158, which is lightly p-type doped, of the gate electrode 128. The second portion 150 prevents n-type dopants of the third portion 135 from counter doping the p-type dopants of the first portion 158. After the resurf implant 156, the resurf resist 152 is removed.

FIG. 1F shows a cross section of the NMOS transistor 101 after a first level of interconnects 168 is complete. In some examples a silicide blocking layer 160 may be formed over the first portion 158 of the gate electrode 128, extending partially over the second portion 150 of the gate electrode 128, and leaving an area of the second portion 150 uncovered by the silicide blocking layer 160. The silicide blocking layer 160 may be formed by depositing one or more sublayers of an oxide, a nitride, an oxynitride, or any combination thereof over the entire wafer and patterning to open areas in which silicide formation is desired. In some examples, a metal silicide layer 162 may be formed on the source region 138, the drain region 139 and exposed portions of the gate electrode 128. The metal silicide layer 162 may provide ohmic electrical connections to the source region 138, the drain region 139, and the gate electrode 128 with lower resistances compared to a similar microelectronic device without metal silicide layer 162.

A pre-metal dielectric (PMD) layer 164 is formed over the top surface 106 of the substrate 103. The PMD layer 164 may include one or more dielectric layers, such as silicon nitride, silicon oxynitride, silicon dioxide, or the like. In some examples, the PMD layer 164 includes a PMD liner and a main dielectric sublayer formed on the PMD liner. Subsequently, the PMD layer 164 may be planarized by a chemical mechanical polish (CMP) process. Contacts 166, e.g. tungsten plugs, are formed within the PMD layer 164 to provide electric connection to the source region 138 and the drain region 139. Interconnects 168 electrically connected to the contacts 166 are formed over the PMD layer 164 using any suitable metallization scheme and provide electrical contact between the NMOS transistor 101 and other components of the microelectronic device 100.

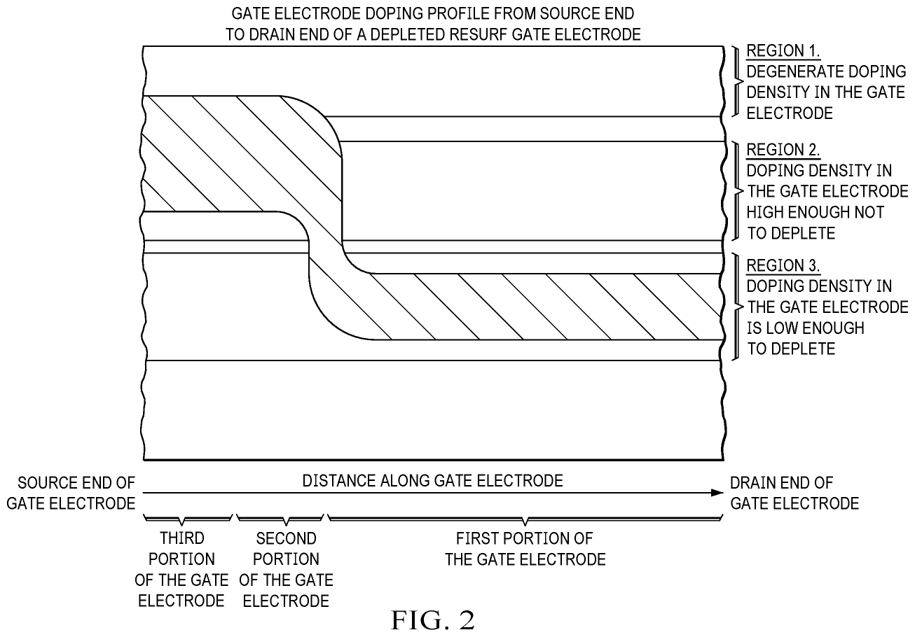

FIG. 2 is a schematic representation of the total dopant atomic concentration (vertical axis) of the NMOS transistor 101 along the gate electrode 128. The gate electrode 128 shows a first region corresponding to the first portion 158 (FIG. 1F) nearest the drain region 139 with a p-type dopant density in a range that allows the first portion 158 to deplete during operation. A second region corresponds to the second portion 150 (FIG. 1F) which is also p-type doped and abuts the first portion 158. The second portion 150 has a p-type doping density such that it may not deplete during operation as shown. A third region corresponds to the third portion 135 (FIG. 1F). The third portion 135 is n-type doped with a doping density such that it will not deplete during operation of the NMOS transistor 101. Thus, third portion 135 may function as a switching element, while the second portion 150 functions as a region that prevents the n-type dopants of the third portion 135 from counter-doping the lightly doped p-type doped first region 158 which provides the resurf region.

FIG. 3A through FIG. 3F are representative of a second type of electronic device to which the principles of the disclosure may be beneficially applied. These figures depict a method of formation for an example microelectronic device 300 including an LDMOS transistor 301 including a depletable resurf gate electrode (gate electrode 328 as shown in FIG. 3B, et seq.). FIG. 3A shows a cross section of the microelectronic device 300 which indicates an area for the LDMOS transistor 301 and is shown after a gate dielectric layer 320 and a gate polysilicon layer 322 have been formed. Earlier processing includes providing a substrate 303 which includes a semiconductor material (e.g., silicon, germanium, or the like), and has a top surface 304. The substrate 303 may include, for example, part of a bulk semiconductor wafer, part of a semiconductor wafer with an epitaxial layer, part of a silicon-on-insulator (SOI) wafer, or other structures suitable for forming the microelectronic device 300.

The substrate 303 may include an optional n-type buried layer (NBL) 306 on a p-type layer 305. The p-type layer 305 may be part of a bulk semiconductor wafer over which the microelectronic device 300 is formed, and may have a p-type dopant concentration between 1×10¹⁸ cm⁻³ to 1×10¹⁹ cm⁻³, for example. Alternatively, the p-type layer 305 may be lightly doped, with an average p-type dopant concentration less than 1×10¹⁸ cm⁻³. The NBL 306 may be 2 μm to 10 μm thick, by way of example, and may have an n-type dopant (e.g., arsenic, antimony) concentration greater than 1×10¹⁹ cm⁻³. The substrate 303 may include an epitaxial layer 308 that includes silicon over the NBL 306. The epitaxial layer 308 may be regarded as part of the substrate 303, and may be 2 μm to 12 μm thick, for example. The epitaxial layer 308 may be p-type, with a dopant concentration of 1×10¹⁵ cm⁻³ to 1×10¹⁶ cm⁻³, or “lightly doped”, by way of example. In versions of examples in which the substrate 303 lacks the NBL 306, the epitaxial layer 308 may be directly on the p-type layer 305. Additionally, the epitaxial layer 308 is optional, and the LDMOS transistor 301 may be formed directly in the p-type layer 305.

An STI structure 310 may be included to provide lateral isolation from other electrical devices over the substrate 303. A field relief dielectric layer 312 may be formed by a LOCOS process, and may have a thickness in a range between 50 nm and 500 nm. The field relief dielectric layer 312 may have a tapered edge along their perimeter where the field relief dielectric layer 312 adjoins the top surface 304 of the substrate 303. The tapered edge of the field relief dielectric layer 312 may be referred to as a “bird's beak” region. Although the example LDMOS transistor 301 illustrated in FIGS. 3A-3F includes the STI structure 310 and the field relief dielectric layer 312, either feature may be omitted in other examples within the scope of the disclosure. For example, the field relief dielectric layer 312 may be replaced with another STI structure. Similarly, the STI structure 310 may be replaced with another LOCOS structure, e.g. similar to the field relief dielectric layer 312.

A drift region 314 is formed in the substrate 303 under the field relief dielectric layer 312 and a portion of the gate dielectric layer 320. One or more n-type implants are performed to form the drift region 314 (which may be referred to as an n-drift region) in the substrate 303. The n-type dopant that defines the n-drift region 314 may be implanted in one step or in multiple steps. For example, phosphorus may be implanted at a total dose of between 1×10¹² cm⁻² and 1×10¹³ cm⁻² with energies suitable for forming the n-drift region 314 with or without subsequent thermal cycles. Arsenic may also be implanted with a similar dose with an energy relatively less than the phosphorus implant.

In addition to the n-drift region 314, a DWELL region 336 is formed. The DWELL region 336 is implanted with p-type dopants which may include boron and/or indium and n-type dopants such as arsenic. The DWELL region 336 may have a p-type peak dopant density between 1×10¹⁷ cm⁻³ and 1×10¹⁹ cm⁻³ at a depth between 0.5 μm and 1.5 μm below the top surface 304. The n-type dopant density is greater than 1×10¹⁸ cm⁻³ and is deposited under conditions such that a p-type/n-type junction depth is between 50 nm and 300 nm below the top surface 304. The DWELL region 336 is p-type with the exception of an n-type region 338 located within the DWELL region 336 as a result of the final distribution of p-type and n-type dopants after a thermal anneal process prior to the stage of processing represented by FIG. 3A. The p-type portion of the DWELL region 336 (in conjunction with the epitaxial layer 308 in some examples) may be referred to a body region (e.g., p-type body region) of the LDMOS transistor 301.

With continuing reference to FIG. 3A, the gate dielectric layer 320 may be formed by thermal oxidation of the top surface 304 by well-known methods, or the gate dielectric layer 320 may be formed by a blanket deposition of a dielectric material such as silicon oxynitride (SiON) over the top surface 304. The gate dielectric layer 320 may have a thickness in a range from about 3 nm to about 50 nm, depending on desired device characteristics. The gate polysilicon layer 322 has been formed in a previous process step, e.g. by a deposition process using one or more silane-based precursors. Alternatively, a replacement gate process may be used. In either case, previously-known or future-developed processes may be used to form the gate polysilicon layer 322 which may have a thickness in a range from approximately 50 nm to 300 nm. The gate polysilicon layer 322 may be undoped or in situ doped as-deposited. In this example formation, the gate polysilicon layer 322 is co-deposited with a p-type precursor such as (diborane, boron trichloride, Tris(2,4 pentanedionato)gallium(III)) such that the p-type dopant dose (the integral of net p-type doping concentration through the thickness of the gate electrode) is between 1×10¹² cm⁻² and 1×10¹³ cm⁻². The low doping concentration in the gate polysilicon layer 322, provides a resurf region to be defined at a later stage of processing.

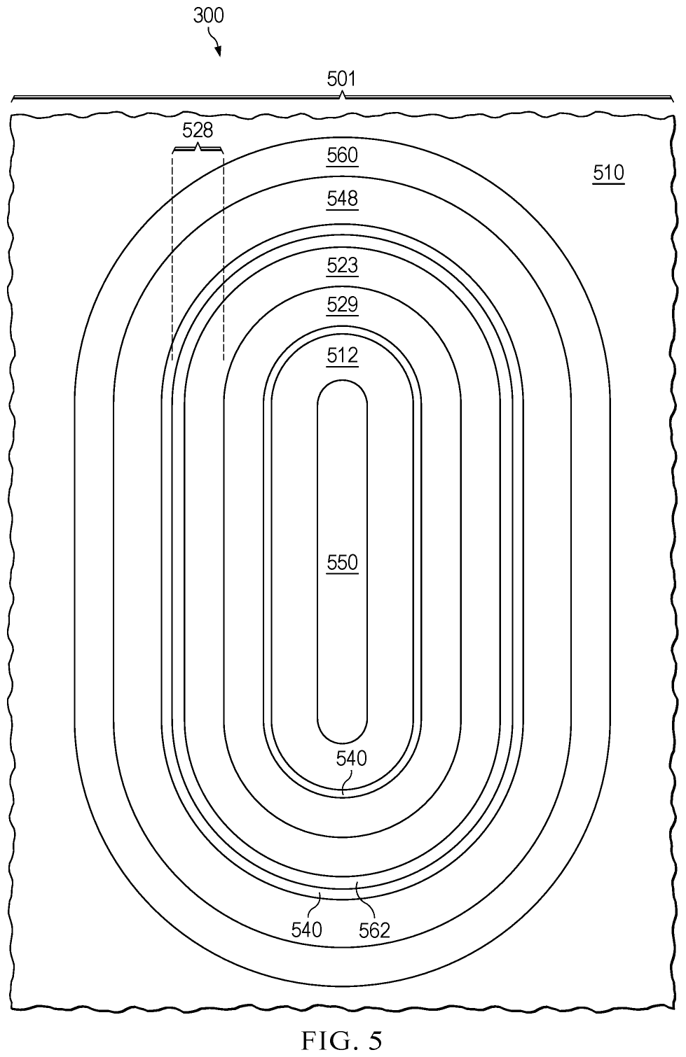

FIG. 3B shows a cross section after a gate resist 324 has been deposited and patterned. A gate plasma etch 326 is used to define a gate electrode 328. The gate electrode 328 may have a racetrack layout as gate electrode 528 illustrated in FIG. 5. After the gate plasma etch 326 is complete, the gate resist 324 is removed. As shown in FIG. 3B, the gate electrode 328 extends over part of the DWELL region 336, part of the n-type region 338, part of the epitaxial layer 308, and part of the n-drift region 314 where these regions intersect the top surface 304. For purposes of discussion the gate electrode 328 is defined as terminating where the gate dielectric layer merges with the field relief dielectric layer 312, with the polysilicon over the field relief dielectric layer 312 being a polysilicon field plate 329. The end of the gate electrode 328 opposite the polysilicon field plate 329 terminates over the DWELL region 336, e.g. over the n-type region 338.

FIG. 3C shows the LDMOS transistor 301 after sidewall spacers 340 are formed on the vertical surfaces (e.g., sidewalls) of the gate electrode 328 and the polysilicon field plate 329. The sidewall spacers 340 may be formed by currently-known or future-developed methods, and may laterally extend 50 nm to 200 nm away from the corresponding sidewall of the gate electrode 328 and the polysilicon field plate 329.

FIG. 3D shows a cross section after a first source/drain resist 342 has been deposited and patterned to a form an opening 344 and an opening 345 for a subsequent first source/drain implant 346. The opening 345 allows n-type dopants from the source/drain implant 346 to be implanted to form the drain region 350, and the opening 344 allows the n-type dopants to form a source region 348. The patterned source/drain resist 342 covers the gate electrode 328 thereby protecting the gate electrode 328 from the first source/drain implant 346. The first source/drain implant 346 conditions may be such that the resulting source region 348 and drain region 350 have a dopant concentration peaking between 1×10¹⁹ cm⁻³ and 1×10²¹ cm⁻³ with the peak doping density between 0.05 μm and 0.03 μm from the top surface 304. The drain region 350 may have an average dopant density at least twice that of the n-drift region 314. The source region 348 may have an average dopant density at least twice that of the DWELL region 336. Although the source region 348 is laterally separated from the edge of the gate electrode 328, the n-type region 338 provides a continuous n-type path underneath the sidewall spacers 340 thereby providing electrical overlap with the gate electrode 328 such that the source region 348 can be electrically coupled to the channel under the gate electrode 328. After the first source/drain implant 346, the source/drain resist 342 is removed.

FIG. 3E shows the LDMOS transistor 301 after a second source/drain resist 354 has been deposited and patterned to form various source/drain resist openings for a second source/drain implant 358. The second source/drain implant 358 may implant p-type dopants into source regions and drain regions of p-channel transistors (not shown) being concurrently formed in the substrate 303. As with the first source/drain implant 346, the second source/drain implant 358 may occur in one or more steps with implant species including boron and/or indium with an overall dose and energy suitable to provide degenerate doping to the source regions and the drain regions of the p-channel transistors, e.g., having an active average dopant density greater than 1×10¹⁹ cm⁻³ near the solubility limit of the dopant atoms in the source region and the drain region.

An opening 356 in the second source/drain resist 354 exposes a portion of the top surface 304 to form a back-gate region 360. The back-gate region 360 forms a continuous p-type conductive path to the DWELL region 336 and to the epitaxial layer 308. The second source/drain resist 354 also includes an opening 357 located to selectively introduce the p-type dopants of the second source/drain implant 358 into a second portion 362 of the gate electrode 328.

As a result of the second source/drain implant 358, the second portion 362 of the gate electrode 328 is heavily p-type doped, e.g. degenerately doped having an active average dopant density greater than 1×10¹⁹ cm⁻³. A first portion 323 of the gate electrode 328 remains lightly p-type doped due to the in-situ doping discussed with respect to FIG. 3A. In other words, the gate electrode 328 has a first portion 323 that is lightly p-type doped and can become depleted during operation of the LDMOS transistor 301. Thus, this first portion 323 of the gate electrode 328 may function as a depleted resurf region. The polysilicon field plate 329 over the field relief dielectric layer 312 abuts the first portion 323 of the gate electrode 328 at the intersection of the field relief dielectric layer 312 and the gate dielectric layer 320 and terminates over the field relief dielectric layer 312. The second portion 362 of the gate electrode 328 abuts the first portion of the of the gate electrode 328 near the intersection of the DWELL region 336 and the epitaxial layer 308 at the top surface 304 of the substrate 303 and terminates over the n-type region 338. The second portion 362 of the gate electrode 328 provides the switching region of the LDMOS transistor 301.

FIG. 3F shows a cross section of the LDMOS transistor 301 after a first level of interconnects 370 is complete. A silicide blocking layer 364 has protected the first portion 323 of the gate electrode 328 from silicide formation, while silicide 366 has been formed over the source region 348, the drain region 350 and the back-gate region 360, as well as partly over the second portion 362 of the gate electrode 328.

A pre-metal dielectric (PMD) layer 368 is formed over the top surface 304 of the substrate 303. The PMD layer 368 may include one or more dielectric layers, such as silicon nitride, silicon oxynitride, silicon dioxide, or the like. In some examples, the PMD layer 368 includes a PMD liner and a main dielectric sublayer formed on the PMD liner.

Contacts 372 through the PMD layer 368 provide electrical contact to the source region 348, the drain region 350 and the back-gate region 360, and interconnects 370 provide electrical connection to other components of the microelectronic device 300. The contacts 372 and interconnects 370 may be formed by any suitable metallization process.

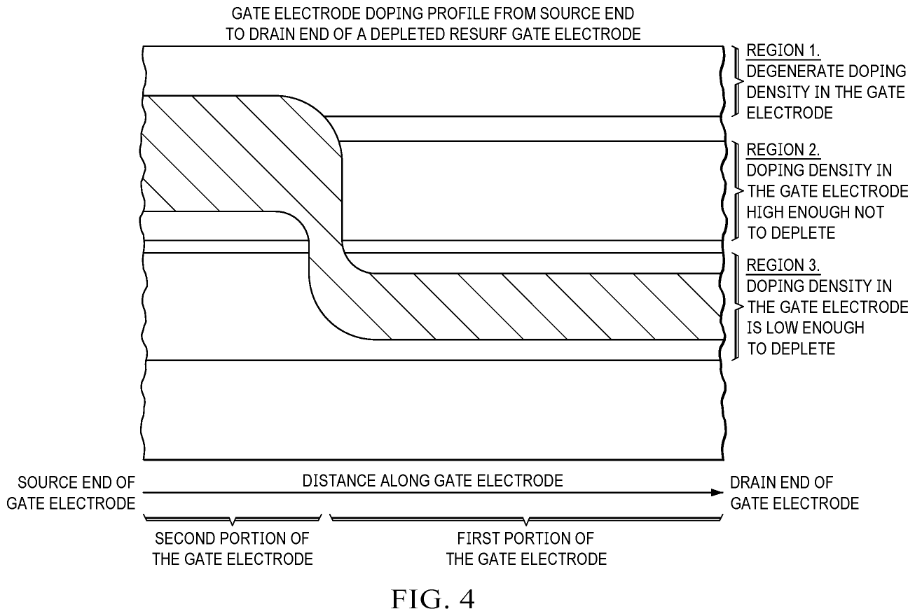

With continuing reference to FIG. 3F, FIG. 4, which is analogous to FIG. 2, shows a schematic representation of the total dopant atomic concentration (vertical axis) of the LDMOS transistor 301 along the axis between the source region 348 and drain region 350 through the gate electrode 328. On the right side of FIG. 4, Region 3 of the dopant concentration is representative of the first portion 323 of the gate electrode 328 nearest the drain region 350. The first portion 323 has a p-type dopant density in a range that allows this part of the gate electrode 328 to deplete during operation of the LDMOS transistor 301. Region 2 of FIG. 4 corresponds to the second portion 362 (FIG. 3F) which is also p-type doped and abuts the first portion 323. The second portion 362 has a p-type doping density such that it will not deplete during operation of the LDMOS transistor 301. Thus, second portion 362 may function as a switching element of the LDMOS transistor 301, while the first portion may provide a resurf effect. It is advantageous for the gate electrode 328 to have an integrated resurf region as the first portion 323 of the gate electrode 328 which provides a depletion region such that during operation the electric field is lower and more uniform across the gate than in a gate electrode with a uniform high level of doping.

FIG. 5 is a top-down view of a microelectronic device 500 including a LDMOS transistor 501 in a racetrack configuration—e.g., a racetrack layout generally having dimensions greater in a first orientation than in a second orientation perpendicular to the first orientation (or generally rectangular layouts with rounded corners). The racetrack configuration may also be referred to as a closed-loop configuration. The LDMOS transistor 501 includes aspects of the LDMOS transistor 501 described with reference to FIGS. 3A through 3F. The LDMOS transistor 501 includes a gate electrode 528 in a racetrack configuration.

As shown in FIG. 5, the drain region 550 may be the linear innermost element of the LDMOS transistor 501, while the other elements shown form a series of concentric closed-loop elements around the drain region 550. The field relief dielectric layer 512 abuts the drain region 550. The other elements of the LDMOS transistor 501 include the field plate 529, the first portion 523 and the second portion 562 of the gate electrode 528, the sidewall 540, the source region 548, the back-gate region 560 and the STI region 510.

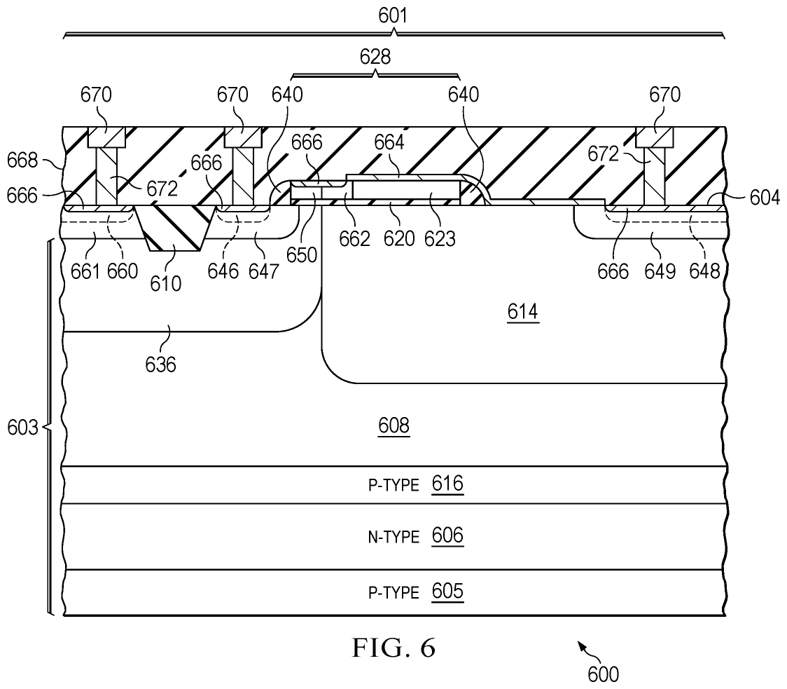

FIG. 6 is representative of a third type of electronic device to which the principles of the disclosure may be beneficially applied. This figure is a cross section of a microelectronic device 600 including a DENMOS transistor 601 with a depletable resurf gate electrode 628. The gate electrode 628 is similar to the gate electrode 128 in FIG. 1A-FIG. 1F in that the gate electrode 628 has a first portion 623 which terminates nearest the drain the first portion 623 being lightly p-type doped and allowing for depletion during operation, a second portion 662 abutting the first portion 623, the second portion 662 being heavily p-type doped which does not deplete during operation, and a third portion 650 abutting the second portion 662, the third portion 650 being heavily n-type doped which does not deplete during operation. As in the structure discussed with respect to FIGS. 1A-1F and FIGS. 3A-3F, the first portion 623 of the gate electrode 628 is lightly p-type doped and functions as a resurf element which lowers the electric field at the drain end of the gate electrode 628 allowing for higher operating voltages and advantageous reliability characteristics with respect to CHC and gate dielectric wear out than a DENMOS transistor 601 without a resurf element. In addition, at some operating voltages, gate electrode 628 including a first portion 623 which acts as a resurf element may be advantageously eliminate the need for a field relief dielectric layer due to the lower and more uniform electric field across the gate electrode 628 as shown in the example DENMOS transistor 601.

Other structural components of the DENMOS transistor 601 include a substrate 603, a top surface 604 of the substrate, a p-type wafer 605, a NBL layer 606, an optional p-type buried layer 616, an epi layer 608, STI isolation 610, a n-type drift region 614, a p-type well 636, a source as implanted region 646, a source after furnace anneal region 647, a drain as implanted region 648, a drain after furnace anneal region 649, a back gate as implanted region 660, a back gate after furnace anneal region 661, a silicide blocking layer 664, a silicide layer 666, a PMD layer 668, contacts 672, and interconnects 670.

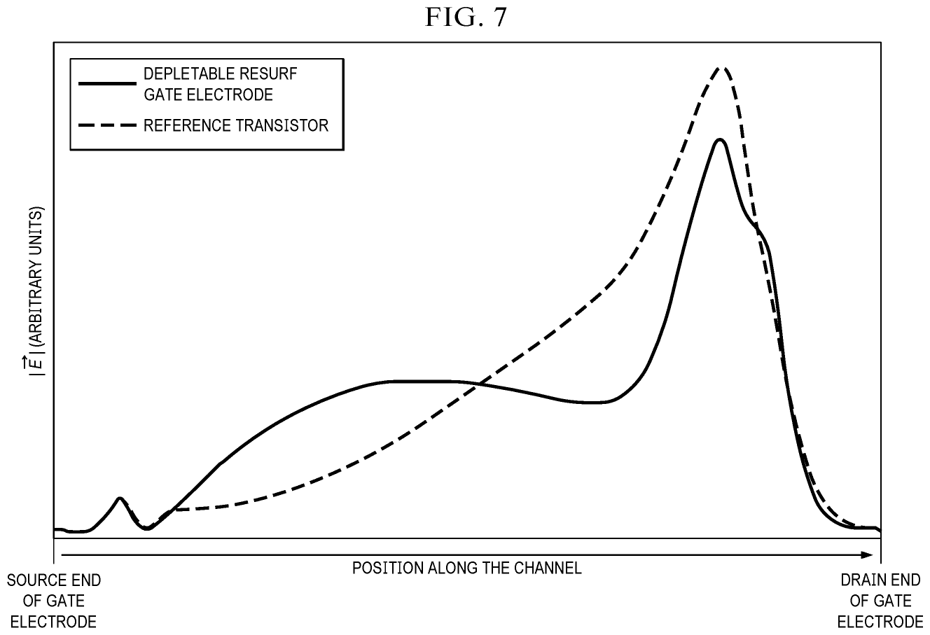

FIG. 7 graphically illustrates some beneficial results of the described principles. Initially referring to FIG. 7, a graph is shown comparing the electric field below the gate electrode of a reference LDMOS transistor (dashed line) to a similar depletable resurf gate electrode LDMOS transistor (solid line) derived from TCAD modeling. The gate electrode of the reference transistor is uniformly n-type doped as may be done conventionally. The depletable resurf gate electrode of the LDMOS transistor has a lightly doped p-type portion analogous to the first portion 158 (FIG. 1F) extending between the drain and the source, and a heavily doped p-type portion analogous to the portion 150 extending from the first portion 158 toward the source. The lightly doped first portion 158 acts as a resurf region of the depletable resurf gate electrode LDMOS transistor. The magnitude of the electric field below the gate electrode is shown between the source region and drain region. The two modeled transistors were simulated operating in a pulsed mode with a pulse length less than 1 μs. As the graph shows, the electric field below the gate electrode of the depletable resurf gate electrode LDMOS transistor is distributed more uniformly than the electric field below the gate electrode of the reference transistor. Furthermore, the peak value of the electric field below the gate electrode is lower near the drain end of the gate electrode for the depletable resurf gate electrode LDMOS. The lower electric field below the gate electrode near the drain of the depletable resurf gate electrode LDMOS is advantageous as it improves reliability characteristics with respect to CHC and gate dielectric wear-out compared to the reference transistor.

Additionally, for the depletable resurf gate electrode LDMOS transistor, the BVDSS in pulsed mode is greater than the BVDSS in DC mode. The increased BVDSS of the depletable resurf gate electrode LDMOS transistor in pulsed mode may be advantageous in applications where tolerance to inductive ringing is desirable.

While various examples of the present disclosure have been described above, it should be understood that they have been presented by way of example only and not limitation. As such, although foregoing examples are described to use various resist layers (e.g., photoresist or photomask layers) to perform various process steps (e.g., implant steps or etch steps), the present disclosure is not limited thereto. For example, one or more hard masks (including one or more layers) may be patterned to define various regions for subsequent process steps to be applied (e.g., regions for receiving dopant atoms, regions to block etchants). Moreover, the resist layers may include multi-level resists instead of a single-level resist in some examples. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the following claims and their equivalents.

What is claimed is:

1. A microelectronic device, comprising:
a source region and a drain region extending into a semiconductor substrate, the semiconductor substrate having a second conductivity type, the source and drain regions having an opposite first conductivity type;
a channel region having the second conductivity type extending between the source region and the drain region; and
a gate electrode over the channel region and having a first portion and a second portion, the first portion having the second conductivity type and a first dopant concentration, and the second portion extending from the first portion toward the source region and having the second conductivity type and a second higher dopant concentration.

2. The microelectronic device as recited in claim 1, further comprising a drain drift region of the first conductivity type that extends from the drain region toward the source region under the first portion, the drain drift region having an average dopant concentration less than the average dopant concentration of the drain region.

3. The microelectronic device as recited in claim 2, further comprising a field relief dielectric layer over the drain drift region, the field relief dielectric layer extending from a gate dielectric layer located under the first portion of the gate electrode, the field relief dielectric layer having a thickness greater than the thickness of the gate dielectric layer.

4. The microelectronic device as recited in claim 1, wherein the channel region includes a DWELL region having the second conductivity type.

5. The microelectronic device as recited in claim 1, wherein the second portion has a second dopant concentration greater than 1×10¹⁸ cm⁻³ and the first portion has a first dopant dose less than 1×10¹³ cm⁻².

6. The microelectronic device as recited in claim 1, wherein the first conductivity type is n-type and the second conductivity type is p-type.

7. The microelectronic device as recited in claim 1, further comprising a silicide blocking layer over the first portion of the gate electrode.

8. The microelectronic device as recited in claim 1, wherein a gate electrode field plate extends from the first portion of the gate electrode toward the drain region, the gate electrode field plate being over a field relief dielectric layer, the gate electrode field plate having the second conductivity type and a same dopant concentration as the first portion.

9. The microelectronic device as recited in claim 1, wherein a third portion of the gate electrode extends from the second portion towards the source region, the third portion having the first conductivity type.

10. The microelectronic device as recited in claim 1, wherein the microelectronic device is selected from the group consisting of a metal oxide semiconductor transistor, a laterally diffused metal oxide semiconductor (LDMOS) transistor, a drain extended metal oxide semiconductor (DENMOS) transistor, a gated bipolar semiconductor device, a gated unipolar semiconductor device, an insulated gate bipolar transistor (IGBT), a metal oxide semiconductor (MOS)-triggered SCR, a MOS-controlled thyristor, and a gated diode.

11. The microelectronic device as recited in claim 1, wherein the gate electrode includes a semiconductor layer selected from the group consisting of polysilicon, poly-SiGe, poly-Ge, and poly-SiC.

12. A method of forming a microelectronic device, comprising:
forming source and drain regions having a first conductivity type extending into a semiconductor substrate having an opposite second conductivity type; and
forming a gate electrode over the semiconductor substrate between the source region and the drain region, the gate electrode having first and second portions having the second conductivity type, the first portion between the second portion and the drain region and having a first dopant concentration, and the second portion having a second higher dopant concentration.

13. The method of claim 12, further comprising forming in the semiconductor substrate a drain drift region having the first conductivity type extending from the drain region toward the source region, extending under the first portion and ending before the second portion, the drain drift region having an average dopant concentration less than an average dopant concentration of the drain region.

14. The method of claim 12, further comprising forming a field relief dielectric layer on a drain drift region, the field relief dielectric layer extending from a gate dielectric toward the drain region and having a thickness greater than the thickness of the gate dielectric layer.

15. The method of claim 12, further comprising forming a DWELL having the second conductivity type in the semiconductor substrate and extending from the source region under the second portion toward the drain region.

16. The method of claim 12, further comprising forming the second portion having a second dopant concentration greater than 1×10¹⁸ cm⁻³ and the first portion having a first dopant dose less than 1×10¹³ cm⁻².

17. The method of claim 12, further comprising forming a silicide blocking layer is over the first portion of the gate electrode and leaving an area of the second portion uncovered by the silicide blocking layer.

18. The method of claim 12, further comprising forming a gate electrode field plate extending from the first portion of the gate electrode toward the drain region, the gate electrode field plate being over a field relief dielectric layer, the gate electrode field plate having the second conductivity type and a same dopant concentration as the first portion.

19. The method of claim 12, further comprising forming a third portion of the gate electrode extending from the second portion toward the source region, the third portion having the first conductivity type with a doping concentration greater than 1×10¹⁸ cm⁻³.

20. The method of claim 12, wherein the first portion of the gate electrode is doped by in-situ doping of a polysilicon layer from which the first portion is formed.

21. The method of claim 12, wherein the first portion of the gate electrode is doped by ion-implantation.
